(19) United States
(12) Patent Application Publication
(10) Pub. No.: US 2025/0157560 A1
(43) Pub. Date: May 15, 2025

(54) NON-DESTRUCTIVE MEMORY SELF-TEST

(71) Applicant: Siemens Industry Software Inc., Plano, TX (US)

(72) Inventors: Benoit Nadeau-Dostie, Gatineau (CA); Wei Zou, Lake Oswego, OR (US)

(73) Assignee: Siemens Industry Software Inc., Plano, TX (US)

(21) Appl. No.: 18/839,926

(22) PCT Filed: Mar. 4, 2022
(86) PCT No.: PCT/US2022/018857

§ 371 Date: Aug. 20, 2024

(51) Int. Cl. G11C 29/14; G11C 29/30; G11C 29/36; G11C 29/44

(52) U.S. Cl. CPC G11C 29/14; G11C 29/30; G11C 29/36; G11C 29/44

(57) ABSTRACT

A memory-testing circuit in a circuit comprises: a test controller; a memory data source selection device configured to select input data for a write port of the memory from test data outputted from the test controller and data from an output of the memory; and a memory address source selection device configured to select an address for an address port of the memory from an address outputted from the test controller and one of one or more preset addresses of the memory. The one or more preset addresses correspond to one or more preserved locations of the memory configured to temporarily store data for one or more locations of the memory to be tested.

### FIELD OF THE DISCLOSED TECHNIQUES

The presently disclosed techniques relates to embedded memory test. Various implementations of the disclosed techniques may be particularly useful for in-system memory test.

### BACKGROUND OF THE DISCLOSED TECHNIQUES

Current high-density semiconductors often include embedded memories. Designed tightly to the technology limits, memories are more prone to failures than other circuits, which can affect not only manufacture yield but circuit reliability adversely. Built-in self-test (BIST) techniques are typically employed to identify defects and problems in the memories. Moreover, a circuit having embedded memories often includes built-in self-repair (BISR) circuitry for performing a repair analysis (built-in repair analysis or BIRA) and for replacing faulty elements with spare ones. Unlike manufacturing testing, in-system testing is often carried out during functional operations of a system. To improve functional safety, for example, chips in a car should be able to detect latent faults not only in logics but also in memories before they affects their operations. This type of in-system testing needs to be performed in a non-destructive (also referred to as transparent) manner, preserving the initial contents of memory cells being tested. However, it is challenging to design a memory test circuit which not only can perform on-line transparent testing without taking the memory-under-test off line for long periods of time but also do not require too large silicon area.

### BRIEF SUMMARY OF THE DISCLOSED TECHNIQUES

Various aspects of the disclosed technology relate to testing memory in a non-destructive manner. In one aspect, there is a memory-testing circuit in a circuit configurable to perform a test on a memory in the circuit while preserving contents of the memory, comprising: a test controller; a memory data source selection device configured to select input data for a write port of the memory from test data outputted from the test controller and data from an output of the memory; and a memory address source selection device configured to select an address for an address port of the memory from an address outputted from the test controller and one of one or more preset addresses of the memory, the one or more preset addresses corresponding to one or more preserved locations of the memory configured to temporarily store data for one or more locations of the memory to be tested in the test.

The one or more preset addresses of the memory may be the first or the last addresses of the memory.

The test may comprises: reading content of the one or more locations of the memory to be tested; writing the content into the one or more preserved locations of the memory; applying a test algorithm to the one or more locations of the memory to be tested; reading the content stored in the one or more preserved locations of the memory; and writing the content stored in the one or more preserved locations of the memory back into the one or more locations of the memory to be tested.

The test controller may generate a first selection control signal for the memory data source selection device and a second selection control signal for the memory address source selection device. The one or more preset addresses may have greater than one addresses and the test controller may generate a third selection control signal for controlling which of the one or more preset addresses to be selected for a write operation or a read operation.

The data from an output of the memory may pass through a comparator, a register, or both before being coupled to an input of the memory data source selection device.

The memory may be a multi-port memory and a port having both read and write capability may be used to write data into the one or more preserved locations of the memory.

In another aspect, there is one or more computer-readable media storing computer-executable instructions for causing a computer to perform a method, the method comprising: creating, in a circuit design, the above memory-testing circuit configurable to perform a test on a memory in the circuit design while preserving contents of the memory.

In still another aspect, there is a method for testing a memory in a circuit performed by a memory-testing circuit in the circuit, comprising: reading content of one or more locations of the memory to be tested; writing the content into one or more preserved locations of the memory; applying a test algorithm to the one or more locations of the memory to be tested; reading the content stored in the one or more preserved locations of the memory; and writing the content stored in the one or more preserved locations of the memory back into the one or more locations of the memory to be tested. The one or more preserved locations of the memory may correspond to first or last addresses of the memory.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed techniques. Thus, for example, those skilled in the art will recognize that the disclosed techniques may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a block diagram of a typical memory.

FIG. 2 illustrates an example of a memory device comprising two memory banks.

FIG. 3 illustrates an example block diagram of a memory-testing circuit configurable to perform a non-destructive test on a memory according to various embodiments of the disclosed technology.

FIG. 4 illustrates a flowchart showing a process of non-destructive memory testing that may be implemented according to various embodiments of the disclosed technology.

FIG. 5 illustrates another example block diagram of a memory-testing circuit configurable to perform a non-destructive test on a memory according to various embodiments of the disclosed technology

FIG. 6 illustrates an example of a multi-port memory along with a memory-testing circuit configurable to perform a non-destructive test on the memory according to various embodiments of the disclosed technology.

FIG. 7 illustrates a programmable computer system with which various embodiments of the disclosed technology may be employed.

### DETAILED DESCRIPTION OF THE DISCLOSED TECHNIQUES

Various aspects of the disclosed technology relate to testing memory in a non-destructive manner. In the following description, numerous details are set forth for the purpose of explanation. However, one of ordinary skill in the art will realize that the disclosed technology may be practiced without the use of these specific details. In other instances, well-known features have not been described in details to avoid obscuring the disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

The detailed description of a method or a device sometimes uses terms like “select,” “generate,” and “perform” to describe the disclosed method or the device function/structure. Such terms are high-level descriptions. The actual operations or functions/structures that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

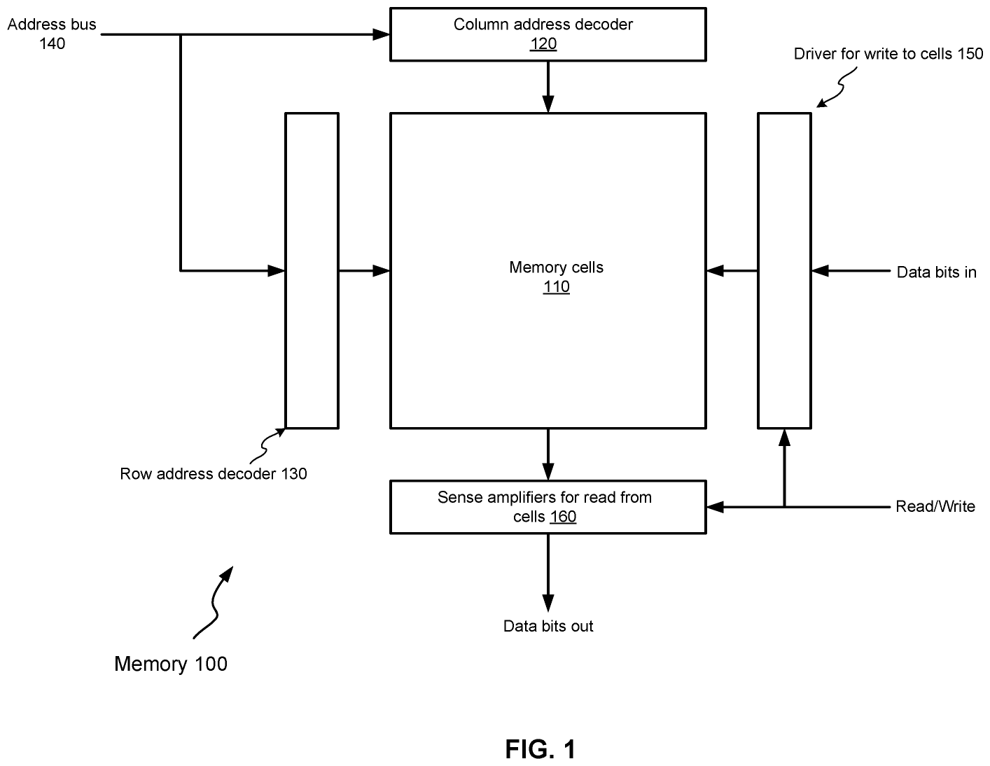

Memories form a large part of system-on-chip circuits. Embedded memories can provide higher bandwidth and consume lower power than stand-alone memories. FIG. 1 illustrates an example of a block diagram of a typical memory 100. The memory 100 comprises memory cells 110, a column address decoder 120, a row address decoder 130, driver circuitry 150, and sense amplifiers 160. The memory cells 110 are connected in a two-dimensional array. Each of the memory cells 110 can store one bit of binary information. The memory cells 110 can be grouped into memory words of fixed word length, for example 1, 2, 4, 8, 16, 32, 64 or 128 bit. It should be noted that the word length is not limited to powers of 2. A memory cell has two fundamental components: storage node and select device. The storage node stores the data bit for the memory cell, and the select device component facilitates the memory cell to be addressed to read/write in an array.

The row address decoder 130 and the column address decoder 120 determine the cell address that needs to be accessed according to a logical address. Based on the address signals outputted from the row address decoder 130 and the column address decoder 120, the corresponding row(s) and column(s) get selected and connected to the sense amplifiers 160 during a read operation. Each of the sense amplifiers 160 amplifies send out a data bit. Similarly, the required cells where the data bits need to be written are selected by the address signals outputted from the row address decoder 130 and the column address decoder 120. To write data bits into memory cells, however, the driver 150 is used. The address information is supplied through an address bus 140.

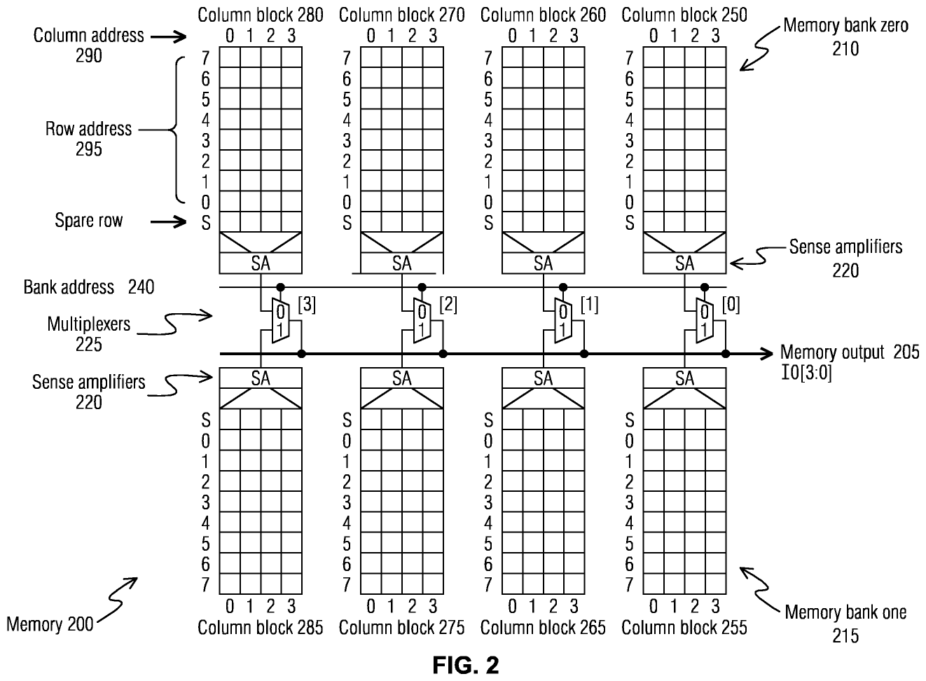

A memory device can have multiple memory banks. A memory bank can comprise multiple rows and columns of memory cells. Typically in a single read or write operation, only one bank is accessed. FIG. 2 illustrates an example of a memory device 200 comprising two memory banks 210 and 215. Each of the memory banks 210 and 215 comprises four column blocks. Column blocks may also be referred to as subbanks. Here, column blocks 250, 260, 270 and 280 belong to the memory bank 210, while column blocks 255, 265, 275 and 285 are components of the memory bank 215. A memory cell in each of the eight column blocks 250-285 is selected by a combination of column address 290 and row address 295. The output for each of the eight column blocks 250-285 is coupled through a multiplexer to one of sense amplifiers 220. Bank address 240 determines, via multiplexers 225, from which memory bank outputs of the sense amplifiers 220 are coupled to memory outputs 205. For example, if the column address 290, the row address 295, and the bank address 240 are 2, 4, and 0, respectively, bits stored at memory cells at column 2 and row 4 of the column blocks 250, 260, 270 and 280 are outputted as bits 0-3 of a word, respectively.

Memories can have a significant impact on yield as they occupy a large area of the system-on-chip design and have a small feature size. However, memory cells typically do not include logic gates and flip-flops. Memory faults thus behave differently than classical stuck-at faults for logic circuits. The large size and high density of memory cell arrays are also not suitable for using external test patterns. As a result, MBIST (memory built-in self-test)-based techniques have become widely adopted for both manufacture testing and in-system testing. MBIST may implement a finite state machine (FSM) to generate and apply stimuli to memories. The responses coming out of memories can then be analyzed to detect faults. MBIST-based techniques often add repair circuitry to the memory-testing circuit. The repair circuitry can analyze testing results and redundancy information and allocate spare rows and/or columns of storage cells to faulty rows and/or columns. The repair can reduce yield loss and extend lifespan of manufactured chips.

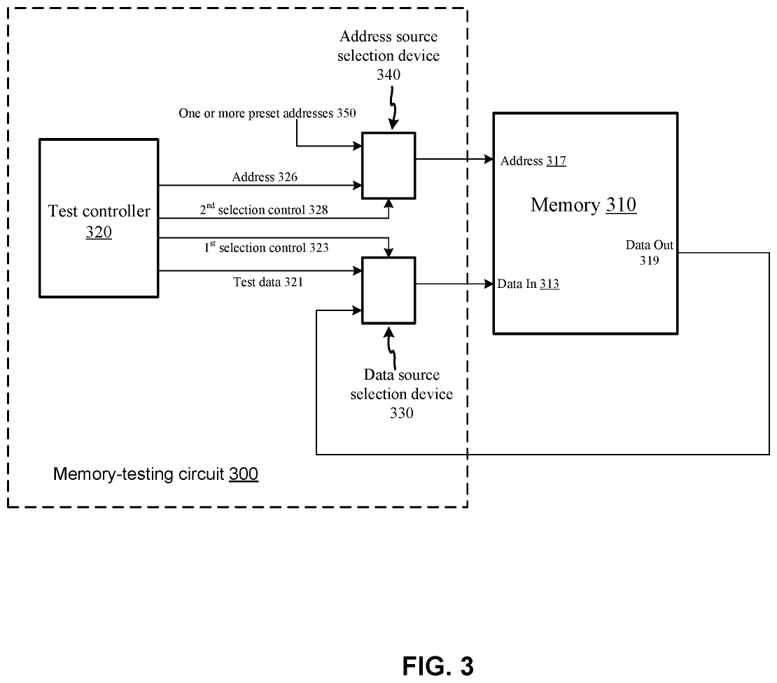

FIG. 3 illustrates an example block diagram of a memory-testing circuit 300 configurable to perform a non-destructive test on a memory 310 according to various embodiments of the disclosed technology. The memory-testing circuit 300 comprises a test controller 320, a memory data source selection device 330, and a memory address source selection device 340. The memory-testing circuit 300 may further comprise a comparator configured to compare output data from the memory 310 with expected data. The memory-testing circuit 300 may still further comprise repair circuitry configured to analyze testing results and redundancy information and allocate spare rows and/or columns of storage cells to faulty rows and/or columns.

The test controller 320 can be implemented using a commercial MBIST controller such as those in the Tessent family available from Siemens Industry Software Inc., Plano, Texas. The test controller 320 comprise a finite-state machine (FSM), a data generator, and an address generator. The finite-state machine can generate control signals to control the data generator, the address generator, the comparator, and other devices such as the repair circuitry in the memory-testing circuit 300. Prompted by the control signals, the data generator and the address generator can generate a test data signal 321 and an address signal 326, respectively. Using the test data signal 321, the address signal 326, and maybe some other control signals, the test controller 320 can make the memory-testing circuit 300 to apply a sequence of reads and writes to the memory 310, which is often referred to as a memory test algorithm. One example of memory test algorithms is March C-algorithm, which includes the following steps: write 0s (to initialize); read 0s, write 1s in an address ascending order (from address 0 to address n−1); read 1s, write 0s in the address ascending order; read 0s, write is in an address descending order (from address n−1 to address 0); read 1s, write 0s in the address descending order, and reads 0s. Another memory test algorithm, Checkerboard algorithm, includes the following steps: write checkerboard in the address ascending order; read checkerboard in the address ascending order; write inverse checkerboard in the address ascending order; and read inverse checkerboard in the address ascending order.

For the non-destructive test, the test controller 320 can be configured to further generate a first selection control signal 323 for the memory data source selection device 330 and a second selection control signal 328 for the memory address source selection device 340. Based on the first selection control signal 323, the memory data source selection device 330 can select input data for a data input port 313 of the memory 310 from data from a data output port 319 of the memory 310 and the test data 321. Based on the second selection control signal 328, the memory address source selection device 340 can select an address for an address port 317 of the memory 310 from one of one or more preset addresses 350 of the memory 310 and the address 326. When the data for the data input port 313 and the one or more preset addresses 350 are selected, the content of one or more locations of the memory 310 to be tested can be temporarily saved in one or more preserved locations of the memory 310 corresponding to the one or more preset addresses 350. The one or more preset addresses of the memory may be the first or the last addresses of the memory. The one or more preset addresses of the memory can be preset using hardware in the memory-testing circuit 300, which is sometimes referred to as being hard-coded. Many memory test algorithms need to access two memory addresses. In this situation, two preset addresses of the memory are used for temporary storage of the memory content being affected by the test. The memory data source selection device 330 and the memory address source selection device 340 can be implemented using multiplexers.

Compared with using dedicated registers near memories as temporary storage devices, the disclosed technology can use smaller silicon area by using locations in the memory under test. Compared with using shared registers in the controller as temporary storage devices, the disclosed technology can allow parallel testing of multiple memories while avoiding routing memory data inputs and outputs to the test controller. Moreover, many memory test technologies require the application of long test algorithms. This can affect the performance of the system as the memories under test needed to be taken off-line for long periods of time during an in-system test. The disclosed technology can avoid this problem by allowing the test to be broken into short bursts whose length can be adjusted to the idle time of the system.

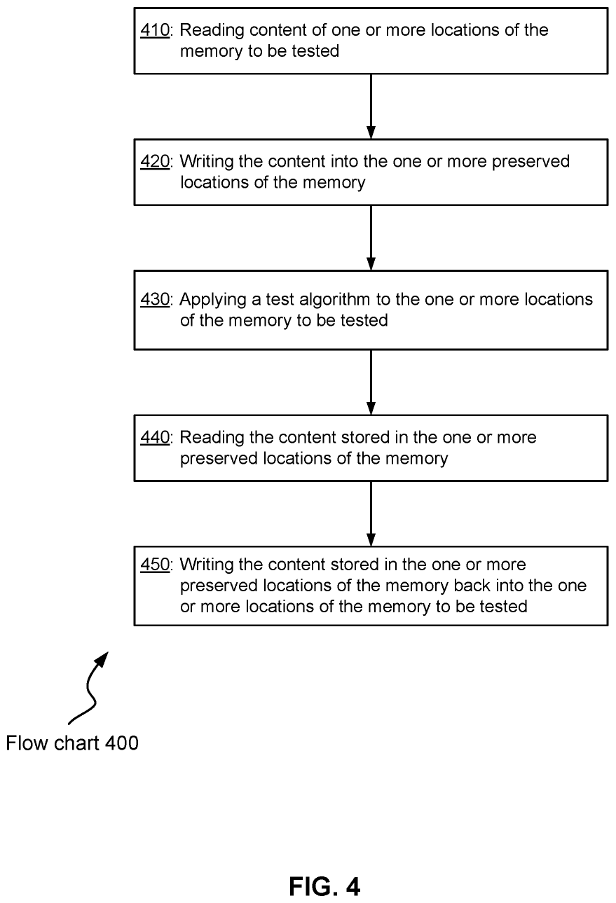

FIG. 4 illustrates a flowchart 400 showing a process of non-destructive memory testing that may be implemented according to various embodiments of the disclosed technology. For ease of understanding, methods of non-destructive memory testing that may be employed according to various embodiments of the disclosed technology will be described with reference to the memory-testing circuit 300 in FIG. 3 and the flow chart 400 illustrated in FIG. 4. It should be appreciated, however, that alternate implementations of a memory-testing circuit may be used to perform the methods of non-destructive memory testing illustrated by the flow chart 400 according to various embodiments of the disclosed technology. Likewise, the memory-testing circuit 300 may be employed to perform other methods of non-destructive memory testing according to various embodiments of the disclosed technology.

In operation 410, the test controller 320 prompts the memory-testing circuit 300 to read content of one or more locations of the memory 310 to be tested. In operation 420, the test controller 320 prompts the memory-testing circuit 300 to write the content just read into the one or more preserved locations of the memory 310 corresponding to the one or more preset addresses 350. The operations 410 and 420 can be performed in a way as follows: reading content of the first location in the one or more locations to be tested; writing the content of the first location into the first location in the one or more preserved locations; reading content of the second location in the one or more locations to be tested; writing the content of the second location into the second location in the one or more preserved locations; and so on.

In operation 430, the test controller 320 prompts the memory-testing circuit 300 to apply a test algorithm to the one or more locations of the memory 310 to be tested. According to some embodiments of the disclosed technology, the test controller 320 can generate a control signal which can prompt the data generator in the test controller 320 to generate test data. The memory-testing circuit 300 can write the test data into the one or more locations of the memory 310. The memory-testing circuit 300 can then read the content of the one or more locations of the memory 310 and compare it with the expected data. Such write and read operations may be repeated using different test data based on the test algorithm. According to some other embodiments of the disclosed technology, the test data to be written into the one or more locations of the memory 310 can be the content temporarily stored in the one or more preserved locations or its derivatives such as the one obtained by inverting digits of the content.

In operation 440, the test controller 320 prompts the memory-testing circuit 300 to read the content stored in the one or more preserved locations. In operation 450, the test controller 320 prompts the memory-testing circuit 300 to write the content stored in the one or more preserved locations back into the one or more locations of the memory 310. Like the operations 410 and 420, the operations 440 and 450 can be performed as follows if the one or more preserved locations correspond to more than one addresses: reading the content stored in the first location in the one or more preserved locations; writing the content stored in the first location in the one or more preserved locations into the first location in the one or more locations which have been tested; reading the content stored in the second location in the one or more preserved locations; writing the content stored in the first location in the one or more preserved locations into the second location in the one or more locations which have been tested; and so on. Alternatively, the content of the last location in the one or more locations which have been tested may be restored first while the content of the first location in the one or more locations which have been tested may be restored last.

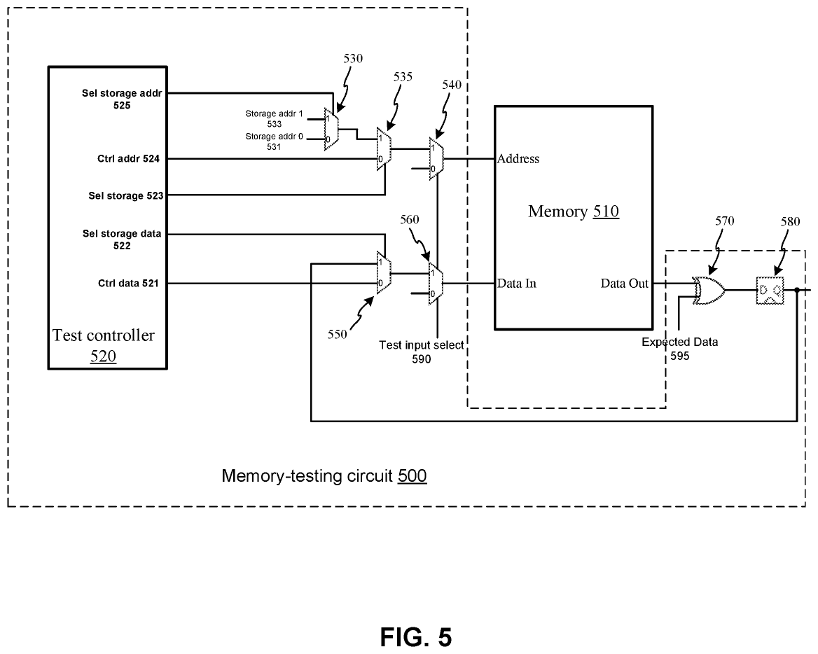

FIG. 5 illustrates another example block diagram of a memory-testing circuit 500 configurable to perform a non-destructive test on a memory 510 according to various embodiments of the disclosed technology. The memory-testing circuit 500 comprises a test controller 520, five multiplexers 530, 535, 540, 550 and 560, an XOR gate 570, and a flip-flop 580. The select inputs of the multiplexers 540 and 560 are coupled to a test input select control signal 590. Based on the test input select control signal 590, address and data inputs of the memory 510 are coupled to either other sources or outputs of the multiplexers 535 and 550, respectively.

The multiplexers 535 and 550 are configured to output test-related address and data signals generated by the memory-testing circuit 500. Based on an address select control signal 523 generated by the test controller 520, the multiplexer 535 can select either a test address signal 524 generated by the test controller 520 or an address signal outputted from the multiplexer 530. Based on a data select control signal 522 generated by the test controller 520, the multiplexer 550 can select either a test data signal 521 generated by the test controller 520 or a signal outputted from the flip-flop 580. The multiplexers 550 and 535 in FIG. 5 operate in a similar way as the memory data source selection device 330 and the memory address source selection device 340 in FIG. 3, respectively.

The test controller 520 also generates a storage address select control signal 525, which controlling whether the multiplexer 530 outputs an address signal provided by either a storage address circuit 533 or a storage address circuit 531. The storage address circuit 531 and the storage address circuit 533 are configured to hard-code two addresses corresponding to two locations in the memory 510 preserved for temporary storage of content of two locations in the memory 510 to be tested.

The XOR gate 570 can operate as a comparator, comparing data read from the memory 510 with expected data 595 during a memory test. The flip-flop 580 can act as a pipeline stage, facilitating timing closure. To temporarily store content of two locations of the memory 510 to be tested in the two preserved locations of the memory 510, the expected data 595 can be set to be “0” in the operation.

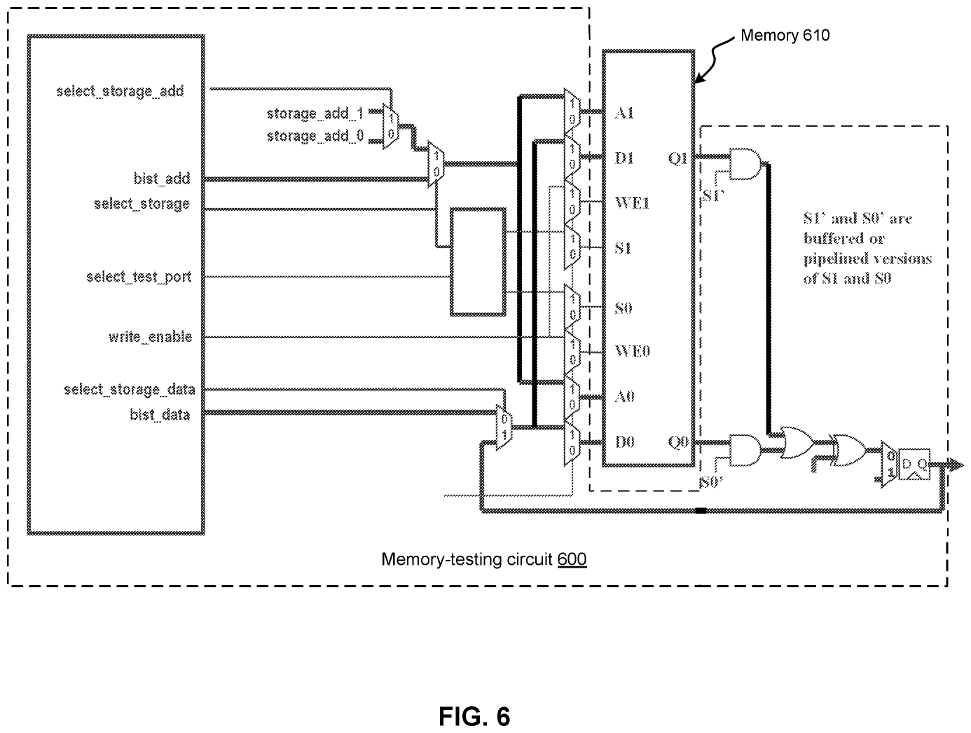

A memory can be a multi-port memory. A multi-port memory can have a read/write port, a read-only port, a write-only port, or some combination thereof. FIG. 6 illustrates an example of a multi-port memory 610 along with a memory-testing circuit 600 configurable to perform a non-destructive test on the memory 610 according to various embodiments of the disclosed technology. The multi-port memory 610 has two read/write ports. The memory-testing circuit 600 can use one of the two read/write ports to access temporary storage locations. According to various embodiments of the disclosed technology, a memory-testing circuit can use a read/write port to access temporary storage locations if the memory has one because this can minimize wire length. If the memory has no read/write port, a test port composed of a read-only and write-only port can be used.

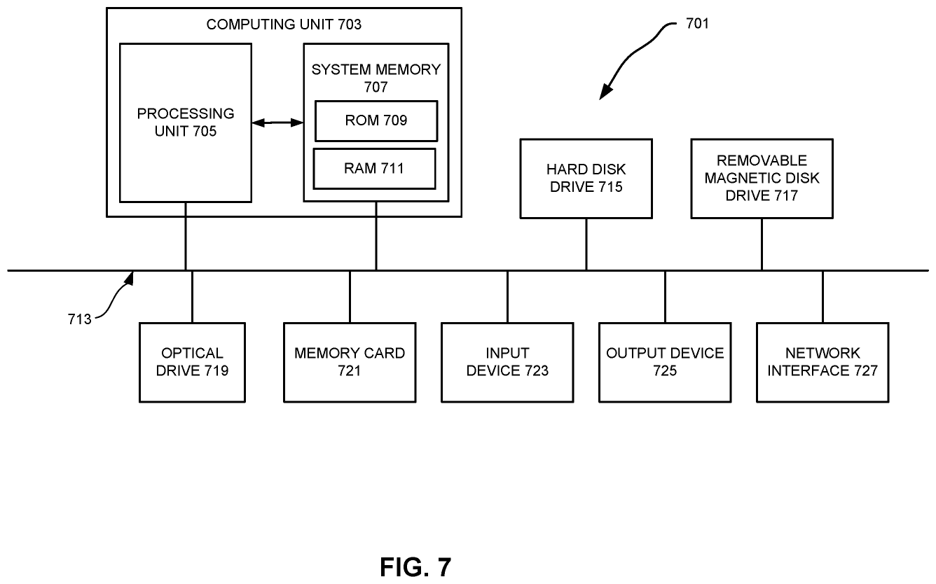

Various examples of the disclosed technology may be implemented through the execution of software instructions by a computing device, such as a programmable computer. Accordingly, FIG. 7 shows an illustrative example of a computing device 701. As seen in this figure, the computing device 701 includes a computing unit 703 with a processing unit 705 and a system memory 707. The processing unit 705 may be any type of programmable electronic device for executing software instructions, but it will conventionally be a microprocessor. The system memory 707 may include both a read-only memory (ROM) 709 and a random access memory (RAM) 711. As will be appreciated by those of ordinary skill in the art, both the read-only memory (ROM) 709 and the random access memory (RAM) 711 may store software instructions for execution by the processing unit 705.

The processing unit 705 and the system memory 707 are connected, either directly or indirectly, through a bus 713 or alternate communication structure, to one or more peripheral devices. For example, the processing unit 705 or the system memory 707 may be directly or indirectly connected to one or more additional memory storage devices, such as a “hard” magnetic disk drive 715, a removable magnetic disk drive 717, an optical disk drive 719, or a flash memory card 721. The processing unit 705 and the system memory 707 also may be directly or indirectly connected to one or more input devices 723 and one or more output devices 725. The input devices 723 may include, for example, a keyboard, a pointing device (such as a mouse, touchpad, stylus, trackball, or joystick), a scanner, a camera, and a microphone. The output devices 725 may include, for example, a monitor display, a printer and speakers. With various examples of the computer 701, one or more of the peripheral devices 715-725 may be internally housed with the computing unit 703. Alternately, one or more of the peripheral devices 715-725 may be external to the housing for the computing unit 703 and connected to the bus 713 through, for example, a Universal Serial Bus (USB) connection.

With some implementations, the computing unit 703 may be directly or indirectly connected to one or more network interfaces 727 for communicating with other devices making up a network. The network interface 727 translates data and control signals from the computing unit 703 into network messages according to one or more communication protocols, such as the transmission control protocol (TCP) and the Internet protocol (IP). Also, the interface 727 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 701 is illustrated as an example only, and it is not intended to be limiting. Various embodiments of the disclosed technology may be implemented using one or more computing devices that include the components of the computer 701 illustrated in FIG. 7, which include only a subset of the components illustrated in FIG. 7, or which include an alternate combination of components, including components that are not shown in FIG. 7. For example, various embodiments of the disclosed technology may be implemented using a multi-processor computer, a plurality of single and/or multiprocessor computers arranged into a network, or some combination of both.

### CONCLUSION

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

What is claimed is:

1. A memory-testing circuit in a circuit configurable to perform a test on a memory in the circuit while preserving contents of the memory, comprising:
a test controller;
a memory data source selection device configured to select input data for a write port of the memory from test data outputted from the test controller and data from an output of the memory; and
a memory address source selection device configured to select an address for an address port of the memory from an address outputted from the test controller and one of one or more preset addresses of the memory, the one or more preset addresses corresponding to one or more preserved locations of the memory configured to temporarily store data for one or more locations of the memory to be tested in the test.

2. The memory-testing circuit recited in claim 1, wherein the one or more preset addresses of the memory are first or last addresses of the memory.

3. The memory-testing circuit recited in claim 1, wherein the test comprises:
reading content of the one or more locations of the memory to be tested;
writing the content into the one or more preserved locations of the memory;
applying a test algorithm to the one or more locations of the memory to be tested;
reading the content stored in the one or more preserved locations of the memory; and
writing the content stored in the one or more preserved locations of the memory back into the one or more locations of the memory to be tested.

4. The memory-testing circuit recited in claim 1, wherein the test controller generates a first selection control signal for the memory data source selection device and a second selection control signal for the memory address source selection device.

5. The memory-testing circuit recited in claim 4, wherein the one or more preset addresses have greater than one addresses and the test controller generates a third selection control signal for controlling which of the one or more preset addresses to be selected for a write operation or a read operation.

6. The memory-testing circuit recited in claim 1, wherein the data from an output of the memory pass through a comparator, a register, or both before being coupled to an input of the memory data source selection device.

7. The memory-testing circuit recited in claim 1, wherein the memory is a multi-port memory and a port having both read and write capability is used to write data into the one or more preserved locations of the memory.

8. One or more computer-readable media storing computer-executable instructions for causing a computer to perform a method, the method comprising:
creating, in a circuit design, a memory-testing circuit configurable to perform a test on a memory in the circuit design while preserving contents of the memory, the memory-testing circuit comprising:
a test controller;
a memory data source selection device configured to select input data for a write port of the memory from test data outputted from the test controller and data from an output of the memory; and
a memory address source selection device configured to select an address for an address port of the memory from an address outputted from the test controller and one of one or more preset addresses of the memory, the one or more preset addresses corresponding to one or more preserved locations of the memory configured to temporarily store data for one or more locations of the memory to be tested in the test.

9. The one or more computer-readable media recited in claim 8, wherein the one or more preset addresses of the memory are first or last addresses of the memory.

10. The one or more computer-readable media recited in claim 8, wherein the test comprises:
reading content of the one or more locations of the memory to be tested;
writing the content into the one or more preserved locations of the memory;
applying a test algorithm to the one or more locations of the memory to be tested;
reading the content stored in the one or more preserved locations of the memory; and
writing the content stored in the one or more preserved locations of the memory back into the one or more locations of the memory to be tested.

11. The one or more computer-readable media recited in claim 8, wherein the test controller generates a first selection control signal for the memory data source selection device and a second selection control signal for the memory address source selection device.

12. The one or more computer-readable media recited in claim 11, wherein the one or more preset addresses have greater than one addresses and the test controller generates a third selection control signal for controlling which of the one or more preset addresses to be selected for a write operation or a read operation.

13. The one or more computer-readable media recited in claim 8, wherein the data from an output of the memory pass through a comparator, a register, or both before being coupled to an input of the memory data source selection device.

14. The one or more computer-readable media recited in claim 8, wherein the memory is a multi-port memory and a port having both read and write capability is used to write data into the one or more preserved locations of the memory.

15. A method for testing a memory in a circuit performed by a memory-testing circuit in the circuit, comprising:
reading content of one or more locations of the memory to be tested;
writing the content into one or more preserved locations of the memory;
applying a test algorithm to the one or more locations of the memory to be tested;
reading the content stored in the one or more preserved locations of the memory; and
writing the content stored in the one or more preserved locations of the memory back into the one or more locations of the memory to be tested.

16. The method recited in claim 15, wherein the one or more preserved locations of the memory correspond to first or last addresses of the memory.
